(19) United States
(12) Patent Application Publication
(10) Pub. No.: US 2026/0276764 A1
(43) Pub. Date: Sep. 17, 2026

(54) Compensating Temperature-Dependent Changes in Magnetic Field

(71) Applicant: Siemens Healthineers AG, Forchheim (DE)

(72) Inventors: Andrew Dewdney, Neunkirchen am Brand (DE); Manuela Rösler, Erlangen (DE); Jeffrey Lyness, Erlangen (DE)

(73) Assignee: Siemens Healthineers AG, Forchheim (DE)

(21) Appl. No.: 19/569,037

(22) Filed: Mar. 17, 2026

(30) Foreign Application Priority Data
Mar. 17, 2025 (DE) 10 2025 110 125.6

(51) Int. Cl. G01R 33/38

(52) U.S. Cl. CPC G01R 33/3804

(57) ABSTRACT

A magnetic resonance device, including: a cold mass with a main magnet; at least one temperature sensor configured to ascertain temperature data of the cold mass; a control unit configured to receive the temperature data from the at least one temperature sensor; and a radio-frequency unit configured to output an output signal in order to generate a radio-frequency field, wherein a system frequency of the magnetic resonance device depends on a temperature of the cold mass, and wherein the control unit and/or the radio-frequency unit are configured to adjust a frequency of the output signal based on the temperature data.

### BACKGROUND

Independent of the grammatical term usage, individuals with male, female, or other gender identities are included within the term.

Magnetic resonance devices are imaging systems that are common in medical diagnostics. They use magnetic fields and radio-frequency fields to generate detailed images of the inside of an examination object. A fundamental component part of a magnetic resonance device is the superconducting main magnet, which generates a static magnetic field (B0 magnetic field). In conventional magnetic resonance devices, the superconducting main magnet is stored in a cryogenic bath (for example, liquid helium), which cools the superconducting main magnet directly and keeps it close to the superconducting temperature. Recently, however, “dry” magnetic resonance devices are increasingly being employed, in which the superconducting main magnet (hereinafter also referred to simply as a “main magnet” or “magnet”) is not stored in a cryogenic bath, rather it is thermally linked to a cryocooler by means of a heat-conducting element.

One of the greatest challenges with magnetic resonance devices is the maintenance of a stable and homogeneous magnetic field under different operating conditions. Temperature fluctuations in actively cooled components of the magnetic resonance device, what is known as the cold mass, can result in undesirable changes in the magnetic field strength and thus in a frequency shift of magnetic resonance signals. This is particularly problematic in “dry” magnetic resonance devices since the magnets are not stored in cryogenic baths and are thus more easily subjected to changes in temperature than conventional helium-cooled systems.

A further problem occurs due to the use of energy-saving operating modes, such as the “EPM” (Eco Power Mode), in which the temperature of the magnet is increased in non-use periods in order to increase an efficiency of the cooling system. While energy-saving modes reduce energy consumption, undesirable temperature deviations can occur in the cold mass, which can have an effect on the magnetic field strength of the generated magnetic field. Furthermore, high-performance gradient systems, in particular, can cause additional thermal stresses in modern magnetic resonance devices, which further impair the magnetic field stability.

Previous solutions, such as premature ending of the energy-saving mode and waiting for a system stabilization, or an increase in the cooling power hours before the scanning procedure, impair either the operational efficiency or the energy savings. These compromises between energy efficiency, image quality, and operational flexibility represent a considerable challenge to the development of magnetic resonance devices.

### SUMMARY

It is therefore an object of the present disclosure to provide an improved magnetic resonance device and a method for compensating temperature-dependent changes in the magnetic field, which overcome these problems.

The object is inventively achieved by the subject matter of the independent claims. Advantageous aspects with expedient developments are the subject matter of the subclaims.

The inventive magnetic resonance device comprises a cold mass with a main magnet, at least one temperature sensor, which is embodied to ascertain temperature data of the cold mass, a control unit, which is embodied to receive the temperature data from the at least one temperature sensor, and a radio-frequency unit, which is embodied to output an output signal in order to generate a radio-frequency field. A system frequency of the inventive magnetic resonance device depends on a temperature of the cold mass. The control unit and/or the radio-frequency unit are embodied to adjust a frequency of the output signal on the basis of the temperature data.

The magnetic resonance device can comprise a cold mass with a main magnet. The cold mass can comprise components of the magnetic resonance device, which are kept at a very low temperature, typically close to absolute zero. The cold mass can have direct thermal contact with a cooling system, for example, a cryocooler. It is conceivable that the cold mass is thermally and mechanically connected to a cryocooler and is actively cooled by means of the cryocooler. Examples of components of the cold mass are the main magnet, a holding structure for the main magnet, and/or a heat-conducting element. A heat-conducting element can be embodied to connect a section of the main magnet thermally and mechanically to a further section of the main magnet and/or a cryocooler.

The main magnet can be a superconducting magnet. It is conceivable that the main magnet comprises a plurality of superconducting magnets or magnetic coils. The superconducting magnetic coils can be arranged concentrically along an axis, in particular a cylinder axis or an axis of rotational symmetry, of the main magnet. In one aspect, the superconducting magnetic coils are spaced apart from one another in the axial direction of the main magnet by means of spacers. The superconducting magnetic coils and the spacers can be mechanically connected together and form a coherent structure. The main magnet can be embodied to generate a static, homogeneous magnetic field (B0 magnetic field), which is necessary for magnetic resonance imaging or magnetic resonance measurement. A magnetic field strength of the magnetic field can be, for example, more than 0.5 tesla, more than 1 tesla, more than 1.5 tesla, or more than 3 tesla.

The magnetic resonance device can have at least one temperature sensor, which is embodied to ascertain or capture temperature data of the cold mass. The at least one temperature sensor can comprise, for example, a thermoelement, a resistance thermometer or another suitable temperature sensor. The at least one temperature sensor can also be embodied to capture a change in a temperature of the cold mass. The change in temperature of the cold mass can result directly, for example, due to a change in the B0 magnetic field, in a change in the system frequency.

The temperature data can comprise items of information about the current temperature of the cold mass and/or a change in temperature of the cold mass. The at least one temperature sensor can be embodied to transmit the temperature data to the control unit and/or the radio-frequency unit of the magnetic resonance device by means of an analog, an optical and/or a digital signal link.

The control unit can be embodied to receive the temperature data from the at least one temperature sensor. The control unit can represent a computer system or another suitable processing unit, which is embodied to process the received temperature data, but also to analyze it. The control unit can represent a central control unit of the magnetic resonance device. However, it is likewise conceivable that the control unit is embodied separately from a central control unit of the magnetic resonance device. For example, the control unit can be embodied as a standalone component or a section of the radio-frequency unit.

The radio-frequency unit can be embodied to output an output signal in order to generate a radio-frequency field or excitation pulse (B1 magnetic field). The radio-frequency field can be used to excite atomic nuclei in an examination object in order to generate magnetic resonance signals for a magnetic resonance imaging. The radio-frequency field can comprise an electromagnetic pulse, in particular a radio-frequency signal.

A system frequency of the magnetic resonance device can depend on a temperature of the cold mass. The system frequency can refer to a resonance frequency or Larmor frequency of atomic nuclei in the magnetic field of the main magnet. Changes in the temperature of the cold mass can result in changes in the magnetic field and therewith to changes in the system frequency.

The system frequency can be regarded as any frequency of the magnetic resonance device that helps to generate the excitation pulse, so when the system frequency changes, the frequency of the excitation pulse would also change. It can be a mixing frequency or a signal that is multiplied in frequency in order to generate the excitation signal. However, it can also be a signal with the system frequency, which is necessary for receiving the nuclear spin resonance signals from the examination object, for example, a mixing frequency for a receiver. The system frequency can also represent the frequency of a digital signal in a digital signal generation or a digital receiver.

With a homogeneous B0 magnetic field, the resonance frequency of atomic nuclei (nuclear spins) is distributed in quite a narrow band (a few hertz to kilohertz) around what is known as the Larmor frequency. An inhomogeneous B0 magnetic field results in a spatial variation of the resonance frequency of nuclear spins, a global variation in the magnetic field value, by contrast, results in a shift of a center of the resonance frequency of the nuclear spins. If the B0 magnetic field varies without the frequency of the excitation pulses being adjusted, the excitation of the nuclear spins by way of the excitation pulse with the B1 magnetic field is not sufficient. This can result in a weak magnetic resonance signal and/or a magnetic resonance signal with localized gaps. Undesirable variations of time-dependent magnetic field portions caused, for example, by eddy currents, which are generated by gradient coils for spatial encoding, can result in effects of this kind. To rectify this problem, for example, the bandwidth of the excitation pulses can be widened, although this results in increased stress on examination objects due to absorbed radio waves. The excitation pulses are limited to a maximum power owing to the limit values for the stress.

The control unit and/or the radio-frequency unit can be embodied to adjust a frequency of the output signal on the basis of the temperature data. This adjustment can make it possible to compensate for shifts in the system frequency owing to changes in the temperature of the cold mass.

Owing to the narrowband resonance frequency of atomic nuclei, even small changes in frequency in the region of a few milli-hertz to hertz can be relevant. Accordingly, even changes in temperature of fractions of a kelvin can cause or necessitate shifts of this kind in the system frequency. An operational change in temperature of the cold mass of the magnetic resonance device can be, for example, less than 0.25 kelvin, less than 0.5 kelvin, less than 0.75 K, less than 1 K, less than 1.25 K, less than 1.5 K, less than 1.75 K or less than 2 K. Greater changes in temperature are to be expected, in particular, when energy-saving modes are applied (such as, the “EPM”). A change in temperature of the cold mass by one kelvin can necessitate, for example, an adjustment of a frequency of the excitation pulse by about 30 Hz to 40 Hz.

The inventive magnetic resonance device can offer a plurality of advantages. For example, more accurate excitation of nuclear spins may be achieved by the adjustment of the frequency of the output signal on the basis of the temperature data. This can result in a higher image quality in the magnetic resonance imaging.

Furthermore, the aspects of the disclosure can enable more efficient use of the magnetic resonance device since waiting times for the stabilization of the magnetic resonance device as a result of temperature fluctuations of the cold mass can be reduced.

Energy consumption of the magnetic resonance device may be improved or optimized, moreover, by way of the adjusting of the frequency of the output signal on the basis of the temperature data in that longer operation in energy-saving modes is enabled without impairing the quality of captured image data.

The inventive magnetic resonance device can be embodied to adjust output signals continuously to a changing Larmor frequency of nuclear spins, which changes as a result of changes in temperature of the cold mass and an altered B0 magnetic field resulting therefrom. As a result, a predetermined image quality of the magnetic resonance device can advantageously be ensured.

In principle, magnetic resonance devices have further components, in particular ones that are not directly cooled, which can have an effect on the B0 magnetic field of the magnetic resonance device. For example, a magnetic resonance device can comprise a shim element and/or an outer vacuum chamber, which can have paramagnetic and/or ferromagnetic materials. If temperature fluctuations occur in the materials of these components, then the B0 magnetic field generated by the main magnet can be distorted by variable magnetic properties of said components. Temperature fluctuations in components of a gradient coil of the magnetic resonance device can occur, moreover, whereby the generated gradient fields can be undesirably distorted. The focus of the present disclosure, by contrast, is on compensating temperature fluctuations in the main magnet, which the B0 magnetic field itself generates. An inventive adjustment of the frequency of the output signal on the basis of the temperature data of the cold mass is not expedient in conventional magnetic resonance devices since the main magnets of conventional magnetic resonance devices are actively cooled and are stored in a cryogenic bath. The present disclosure is based on the recognition that the main magnets of “dry” magnetic resonance devices are affected to a greater extent by temperature fluctuations, in particular if the temperature of the main magnet is varied in the course of energy efficiency measures.

In a preferred aspect, the inventive magnetic resonance device represents a “dry” magnetic resonance device, which comprises a low volume of a cryogen. A low volume can be characterized, for example, by a volume of less than 10 l, less than 5 l or less than 1 l. For example, the inventive magnetic resonance device can comprise one or more small cryogenic tank(s), which are thermally and mechanically connected to the main magnet by means of a heat-conducting element. A cryogenic tank can comprise, for example, a volume of less than 10 l, less than 5 l or preferably less than 1 l cryogen. According to one aspect of the inventive magnetic resonance device, cryogenic tanks are dispensed with completely, so the main magnet is cooled entirely via heat conduction by means of a heat-conducting element. A dry magnetic resonance device can be characterized, moreover, in that immersion of the main magnet in a cryogenic bath is omitted. Preferably, with a dry magnetic resonance device, the main magnet is thermally connected to the cryocooler by means of a fixed heat-conducting element according to an aspect described below.

According to one aspect of the inventive magnetic resonance device, the cold mass comprises a holding structure, which is embodied to hold the main magnet in a predetermined relative position to the magnetic resonance device. The at least one temperature sensor is arranged on the holding structure and embodied to capture temperature data of the holding structure.

The holding structure can be embodied to carry, support, and/or fix the main magnet in a defined position inside the magnetic resonance device. The holding structure can be embodied, moreover, to compensate for electromagnetic forces, which act on the main magnet during magnetic resonance imaging. The holding structure can comprise a rigid and/or resilient material, such as stainless steel or aluminum. Fixing the main magnet in a predetermined relative position to the magnetic resonance device advantageously makes it possible to guarantee a homogeneous B0 magnetic field for imaging.

In one aspect, the holding structure comprises a spacer, which is arranged between a first magnetic coil and a second magnetic coil of the main magnet.

The at least one temperature sensor can be directly arranged on and/or attached to the holding structure. As a result, it is possible to precisely capture temperature fluctuations in the holding structure. The temperature data of the holding structure can provide information about thermal variations, which can have an effect on the magnetic properties, but also a spatial position, of the main magnet.

The temperature data of the holding structure can help to compensate for variations in the B0 magnetic field, which are caused by a change in temperature, but also a thermal expansion or contraction of the holding structure. This can make improved image quality and/or a longer useful life of energy-saving measures possible.

The arrangement of the at least one temperature sensor on the holding structure can offer various advantages. Firstly, direct and accurate measurement of the temperature of a component of the magnetic resonance device can be enabled as a result, which component has a direct thermal and mechanical contact with the main magnet. Secondly, the positioning of the at least one temperature sensor on the holding structure can enable simple installation and maintenance since the holding structure is potentially more easily accessible than other components or sections of the cold mass due to a mechanical coupling to other components of the magnetic resonance device, such as the outer vacuum chamber.

The captured temperature data of the holding structure can be used in conjunction with temperature data of one or more further temperature sensor(s) in order to obtain a comprehensive picture of a temperature distribution of the cold mass of the magnetic resonance device. As a result, more precise adjustment of the frequency of the output signal can be enabled in order to compensate for temperature-dependent changes in the magnetic field.

According to one further aspect of the inventive magnetic resonance device, the at least one temperature sensor is arranged on the main magnet and is embodied to capture temperature data of the main magnet.

The at least one temperature sensor can be attached to a surface of the main magnet. It is conceivable that the at least one temperature sensor has a thermal and mechanical connection to the main magnet. This can make it possible to capture the temperature of the main magnet more accurately. The at least one temperature sensor can comprise, for example, a thermoelement, a resistance thermometer or a thermistor. It is conceivable that the at least one temperature sensor is thermally and mechanically connected to the main magnet by means of a positive connection, a non-positive connection and/or a cohesive connection. For example, the at least one temperature sensor can be thermally and mechanically connected to the main magnet by a glued joint, a screw joint, a clamped joint, a soldered joint, a plug-in connection or the like.

The arrangement of the at least one temperature sensor on the main magnet can be advantageous since changes in temperature of the main magnet can directly influence the generated B0 magnetic field. Direct measurement of the temperature of the main magnet makes it possible to quickly identify changes in temperature of the main magnet and make appropriate adjustments to the frequency of the output signal.

Alternatively, or in addition, the at least one temperature sensor can be arranged on a heat-conducting element, which is thermally connected to the main magnet. The heat-conducting element can be embodied to dissipate thermal energy from the main magnet and/or to improve a thermal connection of a section of the main magnet and a cryocooler.

It is conceivable that the heat-conducting element represents a part or a section of a heat-conducting structure. The heat-conducting element can comprise a solid or be made of a solid. In one aspect, the heat-conducting element comprises a metal with high thermal conductivity, such as copper or aluminum. The heat-conducting element can be embodied, for example, as a wire, a net, a mesh, a rail, or a rod with any desired geometry and/or branching. Arranging the at least one temperature sensor on a heat-conducting element makes it possible to measure the temperature of a further component of the magnetic resonance device directly and accurately, which component has direct thermal and mechanical contact with the main magnet.

The at least one temperature sensor can be embodied to capture the temperature data of the main magnet, the holding structure and/or the heat-conducting element continuously, but also at regular or irregular time intervals. The at least one temperature sensor can be embodied, moreover, to transmit the captured temperature data to the control unit and/or the radio-frequency unit. The control unit and/or the radio-frequency unit can be embodied to make adjustments to the frequency of the output signal on the basis of the temperature data in order to compensate for changes to the B0 magnetic field owing to changes in temperature.

The arrangement of the at least one temperature sensor on the main magnet, a holding structure for the main magnet and/or a heat-conducting element connected to the main magnet can make it possible to capture changes in temperature of the cold mass accurately and promptly, which can have an effect on the B0 magnetic field. This can help to improve the accuracy of the magnetic resonance device.

In one aspect of the inventive magnetic resonance device, the magnetic resonance device comprises a plurality of temperature sensors, which are arranged on the cold mass, and a component of the magnetic resonance device that is not directly cooled. At least one temperature sensor is embodied to capture temperature data of the component of the magnetic resonance device that is not directly cooled. The control unit is embodied to receive the temperature data of the plurality of temperature sensors. The control unit and/or the radio-frequency unit are embodied to adjust a frequency of the output signal on the basis of the temperature data of the plurality of temperature sensors.

The temperature sensors of the plurality of temperature sensors can be arranged at various points of the cold mass and at least one component of the magnetic resonance device, which is not directly cooled, in order to capture a comprehensive thermal profile of components of the magnetic resonance device. The cold mass can comprise, for example, the main magnet, a holding structure of the main magnet, and/or a heat-conducting element. The at least one component which is not directly cooled can comprise, for example, a shim element, a gradient coil connector and/or a wall of an outer vacuum chamber of the magnetic resonance device.

Providing a plurality of temperature sensors on various components of the magnetic resonance device makes it possible to precisely capture temperature gradients and/or temperature fluctuations. As a result, the accuracy of adjustment of the output signal for the compensation of temperature-dependent changes in the magnetic field can be improved or optimized.

The control unit can be embodied to receive and process the temperature data from the various temperature sensors. The processing can comprise averaging or weighting of the temperature data in order to increase the accuracy of the temperature measurement. For example, the control unit can be embodied to weight the temperature data of the temperature sensors as a function of a relevance of the respective temperature sensors and/or a spatial position of the respective temperature sensors relative to the cold mass. The control unit and/or the radio-frequency unit can be embodied to adjust the frequency of the output signal as a function of the processed temperature data.

The inventive magnetic resonance device can advantageously make it possible to capture temperature-dependent influences of various components of the magnetic resonance device and take them into account. This can result in improved compensation of magnetic field distortions, which are caused by temperature fluctuations in different components of the magnetic resonance device.

The arrangement of a plurality of temperature sensors on various components can also help to increase the reliability of the magnetic resonance device. If a temperature sensor should fail, the temperature data of other temperature sensors can potentially still be used for compensating temperature-related changes in the magnetic field.

Capturing temperature data of the cold mass as well as of other components of the magnetic resonance device makes it possible to achieve a more comprehensive understanding of the thermal dynamics of the magnetic resonance device. This can result in more precise and more effective compensation of temperature-dependent changes in the magnetic field and thus improve the image quality and/or reliability of the magnetic resonance device, but also increase the effectiveness of energy efficiency measures.

In one aspect of the inventive magnetic resonance device, the component that is not directly cooled comprises a shim element, a gradient coil connector, and/or a wall of an outer vacuum chamber.

The components that are not directly cooled can represent parts or sections of the magnetic resonance device that have direct thermal contact with a cooling system. A cooling system can comprise a cryocooler, but also any other desired cooling apparatus, such as a water cooling system. The components that are not directly cooled can therefore be subject to temperature fluctuations, which can also have an effect on the B0 magnetic field owing to changed paramagnetic and/or ferromagnetic properties.

A shim element can be an apparatus that is used for fine-tuning the main magnetic field (B0 magnetic field). Shim elements can be made of ferromagnetic material and are strategically arranged in the magnetic resonance device to compensate for inhomogeneities in the main magnetic field. Since shim elements are not directly cooled, changes in temperature can influence their magnetic properties and thus impair the homogeneity of the magnetic field.

A gradient coil connector can represent an electrical connecting element, which connects a gradient coil to a power supply, in particular a control unit and/or a dedicated gradient control unit. Although gradient coils themselves are often actively cooled (for example, by means of a water cooling system), as a component that is not directly cooled, the gradient coil connector can experience changes in temperature. These changes in temperature can influence the electrical properties of the connector and potentially result in changes in the power of the gradient coils.

The wall of an outer vacuum chamber can similarly be regarded as a component that is not directly cooled. The outer vacuum chamber serves to delimit the superconducting components of the magnet from the surroundings and to provide thermal insulation from the surroundings. Although the vacuum chamber itself is not actively cooled, changes in temperature in its structure can result in slight deformations and/or changes in paramagnetic properties, which can in turn influence the magnetic field.

Capturing temperature data from one or more of these component(s) which are not directly cooled can help to attain a more comprehensive or integral picture of the thermal conditions in the magnetic resonance device. These items of information can be used to compensate temperature-related changes in the magnetic field more precisely and thus improve the image quality and accuracy of the magnetic resonance measurements.

An arrangement of at least one temperature sensor on a component that is not directly cooled can make it possible to also capture subtle temperature-dependent influences on the main magnetic field, which would potentially be overlooked otherwise. This can result in improved image quality of the magnetic resonance device, in particular in the case of relatively long imaging examinations, in surroundings with fluctuating ambient temperatures, and/or when energy-saving modes are employed.

In a further aspect of the inventive magnetic resonance device, the control unit and/or the radio-frequency unit are embodied to determine a correlation coefficient between a measured change in temperature and a frequency shift as a function of the temperature data.

The control unit and/or the radio-frequency unit can be embodied to process the temperature data captured by the at least one temperature sensor and a change in temperature of the cold mass, but also to ascertain a component that is not directly cooled.

Furthermore, the control unit and/or the radio-frequency unit can be embodied to capture or calculate a desired frequency shift of the radio-frequency field as a function of the temperature data and/or the changes in temperature of the cold mass.

Capturing the desired frequency shift can comprise receiving items of information with respect to a frequency shift from a database as a function of an ascertained change in temperature of the cold mass.

Calculating the desired frequency shift can comprise measuring, determining, or capturing a change in the main magnetic field as a function of a change in temperature of the cold mass, as well as determining a frequency shift of the radio-frequency field, which compensates the change in the main magnetic field. It is conceivable that the control unit and/or the radio-frequency unit are embodied to capture the change in the main magnetic field as a function of the change in temperature of the cold mass from a database, to calculate it as a function of data from a database, and/or to ascertain it as a function of a model.

Furthermore, the desired frequency shift can also be captured as a function of the correlation coefficient. Analogously to the desired frequency shift, capturing the correlation coefficient can comprise measuring, determining, or capturing a change in the main magnetic field as a function of the change in temperature. Ascertaining the correlation coefficient can also comprise capturing data from a database as a function of an ascertained change in temperature of the cold mass.

In one aspect, the control unit and/or the radio-frequency unit are embodied to ascertain or calculate a change in a Larmor frequency of a nuclear spin as a function of the change in temperature of the cold mass. For example, the change in the Larmor frequency can be captured as a function of the change in temperature of the cold mass from a database, calculated as a function of data from a database and/or be ascertained as a function of a model. The desired frequency shift of the radio-frequency field or the correlation coefficient can be ascertained or calculated accordingly as a function of the change in temperature of the cold mass and the change in the Larmor frequency of the nuclear spin.

The correlation coefficient can represent a measure of the relationship between a change in temperature of the cold mass and a change in the Larmor frequency of a nuclear spin. It is conceivable that the control unit and/or the radio-frequency unit are embodied to adjust the frequency of the output signal as a function of the correlation coefficient in order to compensate changes in the magnetic field owing to changes in temperature of the cold mass. The control unit and/or the radio-frequency unit can be embodied, in particular, to perform the desired frequency shift of the radio-frequency field on the basis of the correlation coefficient.

The magnetic resonance device can have a plurality of temperature sensors, which are embodied to ascertain temperature data of various sections of the cold mass. In one aspect, the control unit and/or the radio-frequency unit are embodied to determine a respective correlation coefficient between a measured change in temperature and the frequency shift as a function of the temperature data of each temperature sensor of the plurality of temperature sensors.

The correlation coefficient can be specified, for example, in the unit Hz/K and thus quantify the frequency shift per kelvin change in temperature. The correlation coefficient can be determined, for example, by means of statistical analysis methods, but also analytical or empirical models. For example, the correlation coefficient can be determined by means of a linear regression as a function of the temperature data and the frequency shift.

A correlation coefficient can enable a computing-efficient and/or robust determination of a desired frequency shift of the radio-frequency field to compensate for changes in temperature of the cold mass. This can help to improve the quality of image data of the magnetic resonance device, in particular in the case of more protracted magnetic resonance imaging and/or when energy-saving modes are employed.

The control unit and/or the radio-frequency unit can be embodied to adjust the frequency of the output signal on the basis of the captured temperature data and the correlation coefficient.

The correlation coefficient can be determined at regular or irregular intervals to enable a timely reaction to changes in the thermal behavior of the magnetic resonance device. This can enable a dynamic adjustment of the radio-frequency field to compensate for temperature fluctuations of the cold mass, but also of a component that is not directly cooled, of the magnetic resonance device.

In one aspect of the inventive magnetic resonance device, the control unit and/or the radio-frequency unit are embodied to average the temperature data and to adjust a frequency of the output signal on the basis of the averaged temperature data.

The control unit and/or the radio-frequency unit can be embodied to process the temperature data captured from the at least one temperature sensor or a plurality of temperature sensors. This processing can comprise averaging of the temperature data, such as the absolute temperature values, the relative temperature values, and/or the changes in temperature. The averaging can comprise, for example, calculation of an arithmetic mean value, a weighted mean, and/or a sliding mean.

In one conceivable aspect of the inventive magnetic resonance device, the control unit and/or the radio-frequency unit are embodied to average the captured temperature data, for example, captured temperature values and/or captured changes in temperature, over a predetermined period. It is conceivable that the captured temperature values and/or changes in temperature are averaged over 0.5, 1, 2, 5 or more seconds.

The averaged temperature data can help to smooth fluctuations in the temperature data (for example, fluctuations in the raw data) and to create a more stable basis for the adjustment of the frequency of the output signal. This can advantageously help to compensate short-term temperature fluctuations and/or noise effects and to enable more precise adjustment of the frequency of the output signal in order to compensate thermally-related changes in the main magnetic field.

The control unit and/or the radio-frequency unit can be embodied to adjust the frequency of the output signal as a function of the averaged temperature data. The frequency of the output signal can be adjusted continuously or in discrete steps. For example, adjustment of the frequency of the output signal can be implemented by changing a digital frequency variable. The digital frequency variable can be used by the radio-frequency unit when providing the output signal.

The use of averaged temperature data for adjusting the frequency of the output signal can make more stable and/or more accurate compensation of thermally-related changes in the main magnetic field possible. As a result, the image quality can be improved and/or the reliability of the magnetic resonance device can be advantageously increased.

Averaging the temperature data and the adjustment of the frequency of the output signal based thereon can make the magnetic resonance device react more flexibly to thermal fluctuations of the cold mass, but components that are not directly cooled. As a result, energy-saving operating modes may be used more effectively without impairing the image quality.

The control unit and/or the radio-frequency unit can be embodied to average the temperature data and adjust the frequency of the output signal in real time. As a result, a continuous compensation of thermally-related changes in the main magnetic field can advantageously be enabled during operation of the magnetic resonance device.

In one aspect of the inventive magnetic resonance device, the control unit and/or the radio-frequency unit are embodied to:
control a frequency of the output signal by means of a digital frequency variable and generate a synthesis signal with the system frequency as a function of the output signal; capture a change in temperature of the cold mass by means of the at least one temperature sensor;
interpolate a temperature-time function as a function of the captured change in temperature of the cold mass;
determine an instant at which a change in the digital frequency variables in a least significant bit causes a change in frequency of the synthesis signal, which corresponds to a change in the system frequency due to a temperature according to the interpolated temperature-time function; and
change the digital frequency variable in the least significant bit at the specific instant.

The control unit and/or the radio-frequency unit can be embodied to control the frequency of the output signal as a function of or by means of the digital frequency variable.

The digital frequency variable can be, for example, a numerical value, which is stored in a register of the control unit and/or the radio-frequency unit. A change in the digital frequency variable makes it possible to precisely control the frequency of the output signal.

In the simplest case, the digital frequency variable can directly specify the Larmor frequency of a nuclear spins. However, a frequency is frequently increased or reduced in the transmitting and/or receiving branch by way of mixing. In this case, it is also conceivable that the system frequency sets or influences one of the two frequencies that are mixed. A frequency multiplication or frequency division of the output signal of the radio-frequency unit is also conceivable. Depending on which, the synthesis signal with the system frequency results directly or also indirectly from the output signal of the radio-frequency unit. In the transmitting and/or receiving branch, the synthesis signal preferably has the Larmor frequency of the nuclear spin as the frequency. In this way, a shift of the local or global Larmor frequency, caused by the change in temperature, in an imaging region of the magnetic resonance device, can be compensated by the radio-frequency unit.

Furthermore, the control unit and/or the radio-frequency unit can be embodied to generate a synthesis signal with the system frequency as a function of the output signal. The synthesis signal can be derived, for example, by mixing or a frequency division, from the output signal and has the system frequency necessary for the magnetic resonance imaging. It is likewise conceivable that the output signal itself is the synthesis signal or that the synthesis signal is obtained therefrom by linear or non-linear processing.

In one aspect of the inventive magnetic resonance device, the system frequency is a frequency of a radio-frequency field (B1 magnetic field) for exciting nuclear spins in the magnetic resonance device.

The control unit and/or the radio-frequency unit can also be embodied to capture a change in temperature of the cold mass by means of the at least one temperature sensor.

The control unit and/or the radio-frequency unit can be embodied to interpolate a temperature-time function as a function of the captured change in temperature on the basis of the captured change in temperature. This interpolation can take place, for example, by way of linear interpolation between successive measuring points or by adjusting a polynomial function to measurement data. The temperature-time function can comprise, for example, changes in temperature, relative temperature values to predetermined initial temperature or absolute temperature values.

Furthermore, the control unit and/or the radio-frequency unit can be embodied to determine an instant at which a change in the digital frequency variables in a least significant bit causes a change in frequency of the synthesis signal. This change in frequency can be selected such that it corresponds to a change in the system frequency due to a temperature according to the interpolated temperature-time function. It is conceivable that the control unit and/or the radio-frequency unit has a computing unit. The computing unit can be embodied to solve the interpolated temperature-time function for a temperature value, which corresponds to a change in the system frequency, which occurs with a change in the least significant bit. An approximation function or a directly predetermined functional relationship can similarly be specified for the dependency of system frequency and frequency variable. The function can be solved analytically or by means of an approximation method.

The least significant bit can represent a least significant bit, which is used in the frequency variables for targeted control of the frequency. It is conceivable that the frequency variable has further bits, which cause even slighter changes in frequency but, owing to a resolution which is no longer physically expedient, is no longer taken into account when setting the system frequency, for example since the resolution is greater than the frequency noise of a master clock or a frequency inaccuracy, caused by a phase noise, of a synthesizer. Such bits can, for example, be set to zero or be occupied by a dither pattern without departing from the scope of the aspects of the disclosure.

Finally, the control unit and/or the radio-frequency unit can be embodied to change the digital frequency variable in the least significant bit at the specific instant. This change can take place, for example, by incrementing or decrementing the value of the digital frequency variables by one or more count(s).

The specific instant within the meaning of the disclosure can also represent a specific time interval from a sequence of time intervals, which is predetermined by a system clock or a sample rate, and in which the specific instant falls. Preferably, a time interval with a change in the least significant bit is followed by one or more time interval(s) without change in the least significant bit or most significant bits.

The inventive adjustment of the digital frequency variables makes it possible to compensate temperature-related changes in frequency continuously and precisely. The inventive magnetic resonance device can advantageously be embodied to reliably capture slight changes in temperature and still avoid greater frequency jumps, which could result in image artifacts, by way of synchronization with and adjusting the change in frequency to the internal system processes.

The inventive method for compensating temperature-dependent changes in the magnetic field of a magnetic resonance device according to an aspect as described above comprises the following steps:
capturing temperature data of the cold mass by means of the at least one temperature sensor;
calculating a frequency shift on the basis of the captured temperature data; and adjusting the frequency of the output signal on the basis of the calculated frequency shift.

The temperature data of the cold mass can be captured by means of one or more temperature sensor(s) according to an aspect as described above. The temperature sensors can be arranged at various points of the cold mass to enable optimally accurate capture of temperature data inside the magnetic resonance device. The cold mass can comprise the main magnet, a holding structure of the main magnet, and/or a heat-conducting element.

The frequency shift can be calculated on the basis of the captured temperature data by means of a control unit and/or a radio-frequency unit of the magnetic resonance device. According to an aspect explained above, the frequency shift can represent a desired frequency shift of a generated radio-frequency field or a shift in a Larmor frequency of a nuclear spin owing to a change in temperature of the cold mass, and optionally a component which is not directly cooled. It is conceivable that a correlation coefficient between a measured change in temperature and the frequency shift is determined. Calculating the frequency shift can comprise averaging the captured temperature data in order to increase the accuracy of the adjustment of the frequency of the output signal.

The frequency of the output signal can similarly be adjusted on the basis of the calculated frequency shift by the control unit and/or the radio-frequency unit. The frequency of the output signal can be adjusted, for example, continuously, but also at regular or irregular time intervals. Optimally precise compensation of the temperature-dependent changes in the magnetic field can be guaranteed as a result.

The inventive method can make it possible to effectively compensate temperature-dependent changes in the magnetic field of a magnetic resonance device. The inventive method can help, for example, to improve or optimize the image quality and/or the energy efficiency of the magnetic resonance device in that it enables precise adjustment of a generated radio-frequency field to the thermal conditions of the cold mass, and optionally a component which is not directly cooled, and thus compensates a temperature-dependent change in a Larmor frequency of nuclear spins within an imaging region of the magnetic resonance device.

The inventive method shares the advantages of the inventive magnetic resonance device according to an aspect as described above.

In one aspect, the inventive method comprises the following step:
generating the output signal by means of the radio-frequency unit as a function of the calculated frequency shift.

The output signal can be generated by the radio-frequency unit of the magnetic resonance device. However, it is likewise conceivable that the control unit actuates the radio-frequency unit to generate the output signal. The generated output signal can have a frequency that is based directly on the previously calculated frequency shift or depends on it.

The radio-frequency unit can be embodied to use the calculated frequency shift as an input variable to adjust the output signal accordingly. This can mean that the frequency of the generated output signal is modified as a function of the calculated frequency shift. For example, the frequency of the generated output signal can be added or subtracted to/from a value of the calculated frequency shift. It is likewise conceivable that the generated output signal is multiplied or divided by the calculated frequency shift.

The generated output signal can serve to generate the radio-frequency field in an imaging region or a patient-receiving region of the magnetic resonance device.

Adjusting the output signal on the basis of the calculated frequency shift can make it possible to achieve an inventive compensation of temperature-related changes in the magnetic field. Generating the output signal as a function of the calculated frequency shift can also enable precise and fast adjustment of the radio-frequency field to a changed Larmor frequency of nuclear spins. This can help to improve the image quality and the accuracy of magnetic resonance imaging in that undesirable effects due to temperature fluctuations of the cold mass, but also components that are not directly cooled, are compensated.

An inventive adjustment of the output signal on the basis of the calculated frequency shift can also help to improve the energy efficiency and/or the availability of the magnetic resonance device. Compensation of temperature-related changes in the magnetic field can potentially make it possible to dispense with energy-intensive measures for cooling the cold mass, and/or long waiting times, which would otherwise be necessary to guarantee a constant magnetic field strength.

In one aspect, the inventive method comprises the following steps:
capturing a change in temperature of the cold mass by means of the at least one temperature sensor;
interpolating a temperature-time function as a function of the captured change in temperature;
determining an instant at which a change in a digital frequency variable in a least significant bit causes a change in frequency of the synthesis signal, which corresponds to a change in the system frequency due to a temperature according to the interpolated temperature-time function;
adjusting the digital frequency variables in the least significant bit at the specific instant; and
generating the output signal by means of the radio-frequency system as a function of the calculated frequency shift, wherein an output frequency of the output signal is dependent on a value of the adjusted digital frequency variable, and a synthesis signal with a system frequency as a function of the output signal.

The change in temperature of the cold mass can be captured by means of one or more temperature sensor(s). The cold mass can comprise the main magnet of the magnetic resonance device, but also a holding structure and/or a heat-conducting element of the main magnet. The change in temperature can relate to a change in temperature that influences the main magnetic field of the magnetic resonance device.

According to an aspect as described above, the temperature-time function can be interpolated by means of a linear interpolation, a polynomial interpolation, or any other desired model function whose parameters can be adjusted by the captured changes in temperature. If more captured measured values exist for the changes in temperature than there are parameters to be adjusted, an optimization method, such as LMS (Least Mean Square) can be applied.

The instant at which a change in the digital frequency variables in the least significant bit causes a change in frequency of the synthesis signal, which corresponds to a change in the system frequency due to a temperature according to the interpolated temperature-time function, can be determined on the basis of the interpolated temperature-time function by means of the control unit and/or the radio-frequency unit. The control unit and/or the radio-frequency unit can be known, like the relationship between the digital frequency variables and the frequency of the output or synthesis signal. This can be specified, for example, as early as during the development of the hardware and software of the magnetic resonance device by way of a proportionality constant predetermined by construction. In this way, the control unit and/or the radio-frequency unit can ascertain which change in frequency of the system frequency corresponds to a change in the least significant bit of the frequency variables.

The digital frequency variables can be adjusted in the least significant bit at the specific instant. A specific instance can be regarded as a time interval which is predefined by a system clock of the magnetic resonance tomograph and in which the value determined from the temperature-time function falls.

The output signal can be generated by means of the radio-frequency unit, with it being possible for the frequency of the output signal to be dependent on the value of the digital frequency variable. The synthesis signal with the system frequency can be generated as a function of the output signal.

The inventive method can enable precise compensation of temperature-dependent changes in the magnetic field in that it allows a fine adjustment of the frequency on the basis of interpolated temperature values. Furthermore, slight changes in temperature of the cold mass may also be reliably captured by means of the inventive method and still prevent greater frequency jumps, which could result in image artifacts, by way of synchronization with and adjustment of the change in frequency to the internal system processes.

The inventive computer program product can be loaded directly into a processor of a programmable controller, with program code means in order to execute all steps of a method according to an aspect as described above when the program product is executed on the controller.

The computer program product can comprise a computer-readable medium on which the program code is saved. The computer-readable medium can be, for example, a non-volatile memory, a hard disk drive, an optical memory medium or a flash memory.

The program code can be written in any desired programming language that is suitable for execution on a processor of a programmable controller. Examples of such programming languages are C, C++, Python or Java.

The programmable controller can comprise a microcontroller, a digital signal processor (DSP), or a Field Programmable Gate Array (FPGA). The programmable controller can be part of a magnetic resonance device and serve to control various components of the magnetic resonance device. The programmable controller can be embodied, in particular, as part of the control unit and/or the radio-frequency unit of the magnetic resonance device.

The program code can comprise instructions in order to execute all steps of an inventive method for compensating temperature-dependent changes in the magnetic field. The computer program product can be embodied to communicate with various sensors, in particular the at least one temperature sensor, as well as the control unit and/or the radio-frequency unit of the magnetic resonance device, in order to capture the required temperature data and to use the frequency shift calculated as a function of temperature data for adjusting the frequency of the output signal.

The use of an inventive computer program product makes it possible to compensate temperature-dependent changes in the magnetic field automatically and efficiently.

The computer program product can be regularly updated or adjusted in order to implement improvements or new functions. The computer program product can also include diagnosis and fault correction functions to identify and rectify potential problems in the compensation process.

### BRIEF DESCRIPTION OF THE DRAWINGS

Exemplary aspects of the disclosure are represented in the drawings and are described in more detail below. Identical reference numerals are used in different figures for identical features. In the drawings:

FIG. 1 shows a schematic representation of a magnetic resonance device;

FIG. 2 shows a schematic cross-sectional view of an exemplary aspect of an inventive magnetic resonance device;

FIG. 3 shows a schematic cross-sectional view of an exemplary aspect of an inventive magnetic resonance device;

FIG. 4 shows a schematic cross-sectional view of an exemplary aspect of an inventive magnetic resonance device;

FIG. 5 shows a flowchart of an exemplary aspect of an inventive method for compensating changes in the magnetic field in a magnetic resonance device; and

FIG. 6 shows a flowchart of a further exemplary aspect of an inventive method for compensating changes in the magnetic field in a magnetic resonance device.

### DETAILED DESCRIPTION

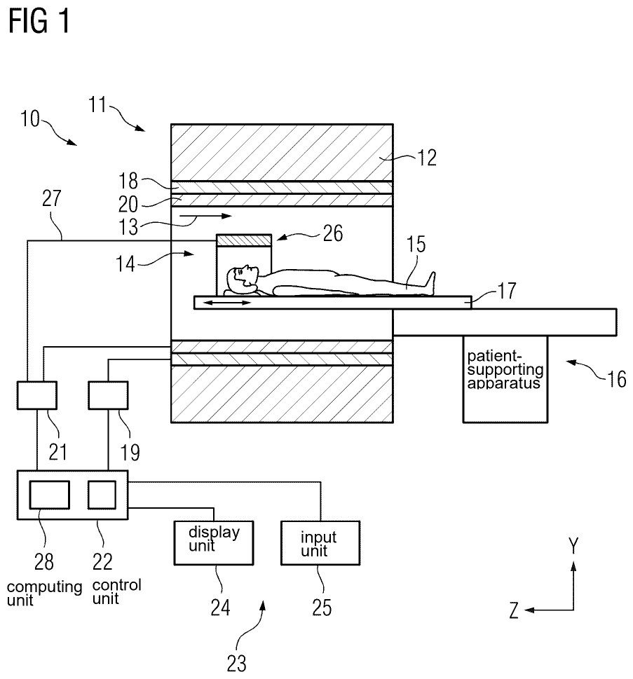

FIG. 1 shows a magnetic resonance device 10. The magnetic resonance device 10 comprises a static field magnet or main magnet 12, which is embodied to provide a homogeneous, static magnetic field 13 (B0 magnetic field). The main magnet 12 comprises one or more superconducting magnet(s) or superconducting magnetic coil(s). The static magnetic field 13 penetrates an imaging region 14 in which an object 15 is positioned for magnetic resonance imaging (magnetic resonance examination). The imaging region 14 can match a patient-receiving region, which is embodied to receive the object 15, in particular a patient, during a magnetic resonance imaging. The imaging region 14 is surrounded at least partially along a circumferential direction by the main magnet 12. The main magnet 12 forms part of the one magnet arrangement 11, which can comprise the main magnet 12, a holding structure (not shown) of the main magnet 12, a heat-conducting element, but also one or more thermal radiation shield(s).

The magnetic resonance device 10 can comprise a patient-supporting apparatus 16, which is embodied to transport the patient 15 into the imaging region 14. In particular, the patient-supporting apparatus 16 can be embodied to transport a diagnostically relevant body region of the patient 15 into an imaging volume or an isocenter (not represented) of the magnetic resonance device 10.

In one aspect, the magnetic resonance device 10 comprises a gradient system with one or more gradient coil(s) 18. The gradient coils 18 can be embodied to generate magnetic field gradients in different spatial directions, preferably orthogonally to one another. The magnetic field gradients can be used for spatially encoding magnetic resonance signals, which are captured during a magnetic resonance examination. The gradient coils 18 can be activated or controlled via a corresponding control signal, which is provided by a gradient control unit 19 or a gradient amplifier. For this purpose, the gradient coils 18 can be electrically connected to the gradient control unit 19 via an electrical signal link 27.

The magnetic resonance device 10 can also comprise an integrated radio-frequency antennas 20 (also referred to as a body coil). The radio-frequency antennas 20 can be activated or controlled by means of a radio-frequency unit 21 or a radio-frequency amplifier. The radio-frequency unit 21 can be embodied to provide an output signal and to control the radio-frequency antennas 20 to generate a radio-frequency field (B1 magnetic field) in the imaging region 14.

In one aspect, the magnetic resonance device 10 comprises a local coil 26. The local coil 26 can be positioned on or in the vicinity of the diagnostically relevant region of the patient 15 (for example, on the head region). The local coil 26 can be embodied to emit radio-frequency fields into the patient 15 and/or receive magnetic resonance signals from the patient 15. It is conceivable that the local coil 26 is controlled by means of the radio-frequency unit 21 and/or a control unit 22. The radio-frequency antennas 20 and/or the local coil 26 can be electrically connected to the radio-frequency unit 21 by means of an electrical signal link 27.

The magnetic resonance device 10 also comprises a control unit 22, which is embodied to control the magnetic resonance device 10. In the example shown in FIG. 1, the control unit 22 comprises a computing unit 28, which is embodied to process magnetic resonance signals and reconstruct magnetic resonance images. The computing unit 28 can also be embodied to process an input by a user of the magnetic resonance device 10 and/or provide an output for the user. For this purpose, the computing unit 28 and/or the control unit 22 can be connected to a display unit 24 and an input unit 25 via a suitable signal link. For processing a magnetic resonance examination, the user can be provided with preparatory items of information, such as imaging parameters, but also items of patient information, by means of the display unit 24. The display unit 24 can comprise, for example, one or more screens or monitors. The display unit 24 can be embodied to display items of control information, such as imaging parameters, for the user. The display unit 24 can furthermore be embodied to provide a graphical user interface with a representation of a diagnostically relevant body region of the patient 15. The input unit 25 can be embodied to receive items of information and/or imaging parameters from the user.

In one aspect, the display unit 24 and the input unit 25 can form part of a user interface 23. The user interface 23 can be connected to the control unit 22 via a suitable signal link.

Of course, the magnetic resonance device 10 can comprise further components and/or functions, which are customary in magnetic resonance devices. The general mode of operation of a magnetic resonance device 10 is known to a person skilled in the art, so a detailed description will be omitted.

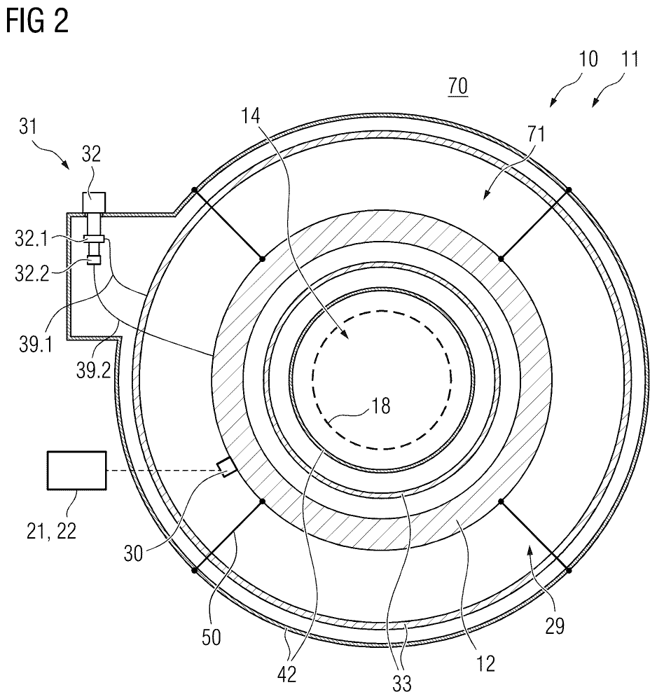

FIG. 2 shows a schematic representation of a cross-section of a magnetic resonance device 10 according to one aspect of the disclosure.

In the example shown, the magnetic resonance device 10 comprises an outer vacuum chamber 42, which forms an outer enclosure for the components of the magnet arrangement. The outer vacuum chamber 42 can separate the surroundings 70 from a vacuum region 71, which is surrounded by the outer vacuum chamber 42. In one aspect, the outer vacuum chamber 42 is embodied as a double-walled hollow cylinder with an outer shell and an inner shell. The outer shell and the inner shell of the outer vacuum chamber 42 can be connected together by means of circular end plates. The components of the magnet arrangement 11 can be accommodated inside the outer shell and the inner shell of the outer vacuum chamber 42, and/or be surrounded by them. The inner shell of the outer vacuum chamber 42 can delimit or enclose the patient-receiving region 14 in the circumferential direction.

In the represented aspect, the magnet arrangement 11 comprises a thermal radiation shield 33. The thermal radiation shield 33 can be embodied as a double-walled hollow cylinder. The main magnet 12 can be encased between an outer wall and an inner wall of the thermal radiation shield 33, to reduce or prevent transport of thermal energy (primary thermal radiation) from the outer vacuum chamber 42 to the main magnet 12.

The magnet arrangement 11 can comprise a holding structure 29, which is embodied to hold the main magnet 12 in a predetermined relative position to the magnetic resonance device 10. In the example represented, the holding structure 29 comprises one or more holding rod(s) 50, which are mechanically connected to the outer shell of the outer vacuum chamber 42 and the main magnet 12. The holding rods 50 can extend through feedthroughs or holes in the thermal radiation shield 33 to produce a mechanical connection between the outer shell of the outer vacuum chamber 42 and the main magnet 12 or further parts of the holding structure 29. Such further parts of the holding structure 29 (not shown) can be embodied to provide mechanical support for the superconducting magnetic coils of the main magnet 12, but also for outer shielding coils (not shown). It is conceivable that the holding structure 29 comprises spacers, which are arranged between individual magnetic coils of the main magnet 12. It is likewise conceivable that the holding structure 29 comprises a cage structure, struts and/or ties, which are embodied to hold the main magnet 12 in the predetermined relative position to the magnetic resonance device.

At least one temperature sensor 30 is arranged inside the outer vacuum chamber 42 to monitor thermal conditions of the cold mass of the magnetic resonance device 10. In the example represented in FIG. 2, the temperature sensor 30 is arranged on the main magnet 12 and is embodied to capture temperature data from the main magnet 12. The temperature sensor 30 can be connected to the control unit 22 and/or the radio-frequency unit 21 by means of a signal link (broken line). The temperature data captured via the temperature sensor 30 can be transmitted to the control unit 22 and/or the radio-frequency unit 21 via the signal link.

The magnetic resonance device 10 also comprises a cryocooler 31, which is embodied to cool the main magnet 12. The cryocooler 31 comprises a cold head 32, which can have a first stage 32.1 and optionally a second stage 32.2. The first stage 32.1 and the second stage 32.2 can be thermally and mechanically connected to components of the magnet arrangement 11 by means of a first heat-conducting element 39.1 and a second heat-conducting element 39.2. In the example shown, the heat-conducting element 39.2 is embodied to connect the second stage 32.2 of the cryocooler 31 thermally and mechanically to the main magnet 12. It is conceivable that the main magnet 12 has further heat-conducting elements 39 (not shown), which are embodied to connect different sections or magnetic coils of the main magnet 12 thermally and mechanically together.

The magnetic resonance device 10 shown in FIG. 2 can comprise further temperature sensors 30. The further temperature sensors 30 can be arranged on the cold mass, but also on components of the magnetic resonance device 10 which are not directly cooled. In one example, at least one further temperature sensor 30 is arranged on a heat-conducting element of the main magnet 12. In a further example, at least one further temperature sensor 30 is arranged on the holding structure 29.

In a preferred aspect, the magnetic resonance device 10 has a plurality of temperature sensors, which are arranged on the main magnet 12. In addition, further temperature sensors 30 can be arranged on the holding structure 29, a heat-conducting element and/or a component of the magnetic resonance device 10 which is not directly cooled.

The control unit 22 and/or the radio-frequency unit 21 can be embodied to process the temperature data provided by the at least one temperature sensor 30 and to adjust a frequency of an output signal of the radio-frequency unit 21 on the basis of the temperature data.

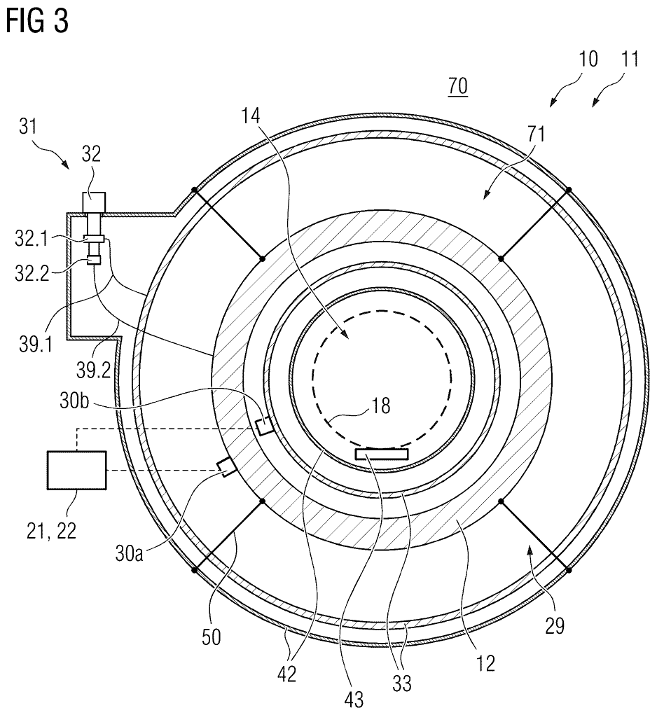

FIG. 3 shows a schematic representation of a magnetic resonance device 10 according to a further aspect of the disclosure. The magnetic resonance device 10 comprises the components of the magnetic resonance device 10 represented in FIG. 2, and these shall not be explained again.

The magnetic resonance device 10 represented in FIG. 3 comprises a gradient cooling facility 43, which is embodied to cool one or more gradient coil(s) 18. Furthermore, the magnetic resonance device 10 comprises two temperature sensors 30a and 30b, which are arranged inside the outer vacuum chamber 42 to monitor thermal conditions of the magnetic resonance device 10.

In the example represented in FIG. 3, the temperature sensor 30b is arranged on the inner shell of the outer vacuum chamber 42 and is embodied to capture temperature data from the inner shell of the outer vacuum chamber 42. The temperature sensors 30a and 30b can be connected to the control unit 22 and/or the radio-frequency unit 21 via signal links (broken lines). The temperature data captured by means of the temperature sensor 30b can thus be transmitted to the control unit 22 and/or the radio-frequency unit 21 via a signal link.

The signal links between the temperature sensors 30a, 30b and the control unit 22 and/or radio-frequency unit 21 can be embodied as tethered signal links (for example, an electrical or optical signal link) or wireless signal links.

The control unit 22 and/or the radio-frequency unit 21 can be embodied to process the temperature data provided by the temperature sensors 30a and/or 30b and to adjust a frequency of an output signal of the radio-frequency unit 21 on the basis of the temperature data. In particular, the control unit 22 and/or the radio-frequency unit 21 can be embodied to capture temperature data of the cold mass as well as of one or more component(s) of the magnetic resonance device 10 which are not directly cooled by means of a plurality of temperature sensors 30, 30a, 30b (and optionally further temperature sensors 30) and to adjust a frequency of the output signal on the basis of the temperature data.

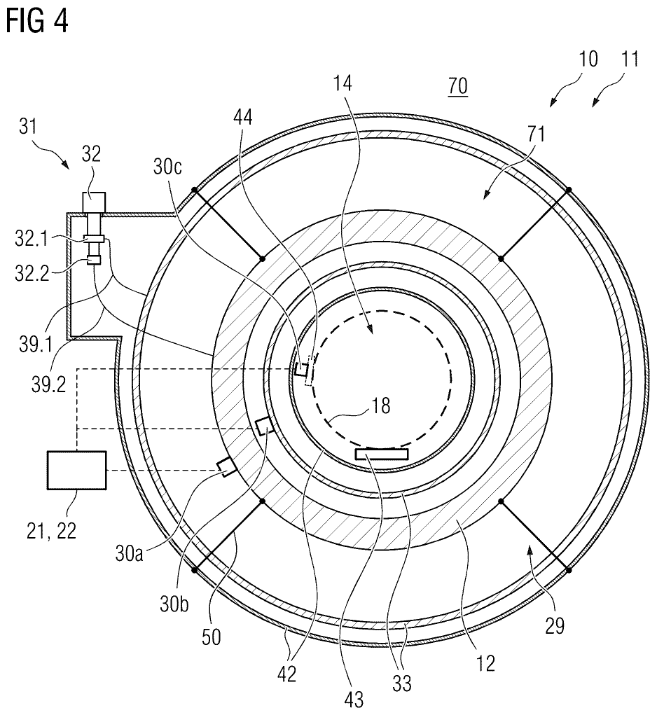

FIG. 4 shows a schematic representation of a magnetic resonance device 10 according to one aspect of the disclosure. The illustrated magnetic resonance device 10 can comprise all components of the magnetic resonance device 10 represented in FIGS. 2 and 3.

In the aspect represented in FIG. 4, the magnetic resonance device 10 comprises at least three temperature sensors 30a, 30b and 30c, which are arranged inside an outer vacuum chamber 42 to monitor thermal conditions inside the magnetic resonance device 10. The temperature sensor 30a is arranged on a component of the cold mass, while the temperature sensors 30b and 30c are arranged on components of the magnetic resonance device 10 which are not directly cooled, for example on the inner shell of the outer vacuum chamber 42 and a shim element 44.

In the present case, the temperature sensor 30c is embodied to capture temperature data from the shim element 44. The temperature sensor 30c can be connected to a control unit 22 and/or a radio-frequency unit 21 via a signal link (broken line). The temperature data captured by the temperature sensor 30c can be transmitted to the control unit 22 and/or the radio-frequency unit 21 via the signal link. The signal link can be embodied as a tethered signal link (for example, an electrical or optical signal link) or a wireless signal link.

Arranging the three temperature sensors 30a, 30b and 30c on the cold mass as well as on components of the magnetic resonance device 10 which are not directly cooled makes comprehensive monitoring of the thermal conditions possible. This can make improved compensation possible of changes in the magnetic field as a consequence of thermal fluctuations of cooled components and components of the magnetic resonance device 10 which are not directly cooled and variations associated therewith in the Larmor frequency of nuclear spins.

Of course, the aspects of the inventive magnetic resonance device 10 shown in FIGS. 2 to 4 can comprise further temperature sensors, which are arranged on components of the cold mass and/or components which are not directly cooled. In one aspect, the magnetic resonance device 10 has one or more temperature sensor(s), which are arranged on a holding structure 29, a heat-conducting element, on a shim element 44, a gradient coil connector (not shown) and/or a wall of the outer vacuum chamber 42.

The control unit 22 and/or the radio-frequency unit 21 can be embodied to process the temperature data provided by the temperature sensors 30a, 30b and 30c (and optionally further temperature sensors 30) and to adjust a frequency of an output signal of the radio-frequency unit 21 as a function of the temperature data.

In one aspect, the control unit 22 and/or the radio-frequency unit 21 of the inventive magnetic resonance device 10 are embodied to determine a correlation coefficient between a measured change in temperature and a frequency shift as a function of the temperature data. The correlation coefficient can be ascertained, in particular, by a computing unit 28 of the control unit 22. The control unit 22 and/or the radio-frequency unit 21 can also be embodied to adjust the frequency of the output signal on the basis of the calculated frequency shift.

In a further aspect, the control unit 22 and/or the radio-frequency unit 21 of the inventive magnetic resonance device 10 are embodied to average the temperature data, and to adjust a frequency of the output signal on the basis of the averaged temperature data.

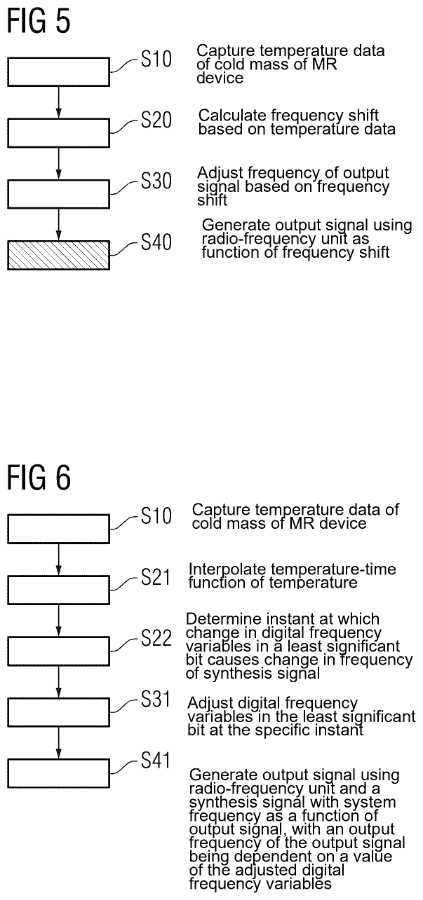

Each of the aspects of the magnetic resonance device 10 represented in FIGS. 2 to 4 can be embodied to execute the steps of an aspect of an inventive method for compensating temperature-dependent changes in the magnetic field of a magnetic resonance device 10. Illustrative aspects of the inventive method are described in FIGS. 5 and 6.

FIG. 5 shows a schematic representation of a method for compensating changes in the magnetic field in a magnetic resonance device.

In a step S10 of the method, temperature data of the cold mass of the magnetic resonance device is captured by means of at least one temperature sensor (30). In one aspect, the temperature data is captured from a main magnet 12, a holding structure for the main magnet 12 and/or a heat-conducting element. Capturing temperature data can comprise, in particular, capturing relative temperatures, absolute temperatures and/or changes in temperature. It is conceivable that changes in temperature of components of the magnetic resonance device 10 can be ascertained by repeated capture of relative or absolute temperatures of the components of the magnetic resonance device.

Optionally, step S10 can comprise capturing temperature data of a component of the magnetic resonance device 10 which is not directly cooled, such as a wall of an outer vacuum chamber 42, a shim element 44 and/or a gradient coil connector.

In a step S20, a frequency shift is calculated on the basis of the temperature data, in particular the changes in temperature, of the cold mass. Calculating the frequency shift can comprise converting a change in temperature based on the temperature data into a corresponding adjustment of a frequency of an output signal of the radio-frequency unit 21. It is conceivable that the frequency shift is calculated by means of the control unit 22 and/or computing unit 28 of the magnetic resonance device 10.

A step S30 comprises adjusting the frequency of the output signal on the basis of the calculated frequency shift. Adjusting the frequency of the output signal can compensate the change in magnetic field induced as a consequence of a captured change in temperature.

Optionally, the inventive method comprises the further step S40 of generating the output signal by means of the radio-frequency unit 21 as a function of calculated frequency shift. It is conceivable that the output signal is generated by the control unit 22 and transmitted to the radio-frequency unit 21. It is likewise conceivable that the control unit 22 actuates the radio-frequency unit 21 to generate the output signal.

The inventive method can provide a systematic approach to the compensation of changes in temperature, in particular changes in temperature of the cold mass, of the magnetic resonance device 10.

FIG. 6 shows a schematic representation of an aspect of an inventive method for compensating changes in the magnetic field in a magnetic resonance device 10.

In a step S10 of the method, a change in temperature of the cold mass and optionally a component of the magnetic resonance device 10 which is not directly cooled is captured by means of at least one temperature sensor 30. The change in temperature can be captured for an individual temperature sensor or also for a plurality of temperature sensors. The temperature data of the temperature sensors can be averaged and/or weighted. In one aspect, the measured values are averaged over time when capturing the change in temperature in order to reduce short-term interference and noise components.

The step S20 of calculating the frequency shift on the basis of captured temperature data can take place by way of steps S21 and S22.

Step S21 can include interpolating a temperature-time function of the temperature using the captured changes in temperature.

The interpolation can take place by way of a linear interpolation, a polynomial interpolation or another model function whose parameters are adjusted by the captured changes in temperature. If more captured measured values exist for the changes in temperature than there are parameters to be adjusted, an optimization method, such as LMS (Least Mean Square) can be applied.

In one aspect, the control unit 22 and/or the radio-frequency unit 21 can use further input parameters in addition to the captured changes in temperature when determining the temperature-time function. For example, the control unit 22 can obtain further items of information, which are relevant to a future temperature profile. These are, for example, items of information about an up-to-date current through a gradient coil 18 and/or about a radio-frequency power of output signals or synthesis signals, which generate the radio-frequency field. On the basis of the imaging sequences used, the control unit 22 can predict these values also for the future, moreover, and optionally convey them to the radio-frequency unit 21. The temperature-time function may be more precisely determined in the future on the basis of these items of information. In particular, if a change takes place between imaging sequences or, for example, breaks are necessary for operating procedures, the accuracy of the temperature-time function with respect to a determination can thereby be fundamentally improved solely on the basis of the captured changes in temperature.

A further step S22 comprises determining an instant at which a change in the digital frequency variables in a least significant bit causes a change in frequency of the synthesis signal, which corresponds to a change in the system frequency due to a temperature according to the interpolated temperature-time function.

The control unit 22 and/or the radio-frequency unit 21 can have items of information available with regard to a relationship between change in temperature and change in the system frequency. Such a relationship can exist, for example, as a model function or as a value table on the basis of model calculations or measurements. However, such a relationship can also be regarded as a correlation coefficient or a series of correlation coefficients according to an aspect as described above. Thus, using the temperature-time function, the control unit 22 and/or the radio-frequency unit 21 can ascertain at which instant the change in temperature corresponds to a change in frequency of the system frequency, which corresponds to a change in the least significant bit.

Step S30 of adjusting the frequency of the output signal on the basis of the calculated frequency shift can take place by way of step S31.

Step S31 comprises adjusting the digital frequency variables in the least significant bit at the specific instant.

The specific instant does not necessarily have to correspond to an instant at which new temperature data or changes in temperature are captured. Instead, the frequency variables can also be adjusted in small steps at numerous instants between capturing temperature data, for example if a rate of temperature change and a rate of frequency change of the system frequency, caused thereby, is high. In this way it is possible to avoid greater frequency jumps over greater time intervals.

An instant within the meaning of the disclosure is also viewed as a time interval which is specified by a system clock of the magnetic resonance device 10 and in which the value determined from the temperature-time function falls. Preferably, there are one or more time interval(s) without change in the frequency variables between the time intervals in which there is a change in the frequency variables. The time intervals can comprise, for example, milliseconds or multiples of a system clock and follow each other without overlapping, or overlapping only slightly, in the process.

In a further step S41, an output signal is generated by means of the radio-frequency unit 21 and a synthesis signal with the system frequency as a function of the output signal, with an output frequency of the output signal being dependent on a value of the adjusted digital frequency variables.

The schematic representations shown in the described Figures do not depict any scale or size ratios.

The aspects of the disclosure described above in detail are merely exemplary aspects which can be modified in a wide variety of ways by a person skilled in the art without departing from the scope of the disclosure. For example, features of individual aspects can be combined with features of other aspects unless such a combination was explicitly ruled out. The steps of the inventive method are not limited to the described order either, rather they can be executed in a different order and/or can partially or completely overlap time-wise.

Furthermore, use of the indefinite article “a” or “an” does not preclude the relevant features from also being present multiple times. Similarly, the terms “unit” and “element” do not preclude the relevant components from being composed of cooperating sub-components, which can possibly also be spatially distributed.

1. A magnetic resonance device, comprising:
a cold mass with a main magnet;
at least one temperature sensor configured to ascertain temperature data of the cold mass;
a control unit configured to receive the temperature data from the at least one temperature sensor; and
a radio-frequency unit configured to output an output signal to generate a radio-frequency field,
wherein a system frequency of the magnetic resonance device depends on a temperature of the cold mass, and wherein the control unit and/or the radio-frequency unit are configured to adjust a frequency of the output signal based on the temperature data.

2. The magnetic resonance device as claimed in claim 1, wherein the cold mass comprises a holding structure configured to hold the main magnet in a predetermined relative position to the magnetic resonance device, and wherein the at least one temperature sensor is arranged on the holding structure and configured to capture temperature data of the holding structure.

3. The magnetic resonance device as claimed in claim 1, wherein the at least one temperature sensor is arranged on the main magnet and/or a heat-conducting element of the main magnet.

4. The magnetic resonance device as claimed in claim 1, further comprising:
a plurality of temperature sensors arranged on the cold mass and a component of the magnetic resonance device which is not directly cooled,
wherein at least one temperature sensor is configured to capture temperature data of the component of the magnetic resonance device which is not directly cooled,
wherein the control unit is configured to receive the temperature data of the plurality of temperature sensors, and
wherein the control unit and/or the radio-frequency unit are configured to adjust a frequency of the output signal based on the temperature data of the plurality of temperature sensors.

5. The magnetic resonance device as claimed in claim 4, wherein the component which is not directly cooled comprises a shim element, a gradient coil connector, and/or a wall of an outer vacuum chamber.

6. The magnetic resonance device as claimed in claim 1, wherein the control unit and/or the radio-frequency unit are configured to determine a correlation coefficient between a measured change in temperature and a frequency shift as a function of the temperature data.

7. The magnetic resonance device as claimed in claim 1, wherein the control unit and/or the radio-frequency unit are configured to average the temperature data, and to adjust a frequency of the output signal based on the averaged temperature data.

8. The magnetic resonance device as claimed in claim 1, wherein the control unit and/or the radio-frequency unit are configured to:
control a frequency of the output signal using a digital frequency variable and generate a synthesis signal with the system frequency as a function of the output signal;
capture a change in temperature of the cold mass using the at least one temperature sensor;
interpolate a temperature-time function as a function of the captured change in temperature of the cold mass;
determine an instant at which a change in the digital frequency variables in a least significant bit causes a change in frequency of the synthesis signal, which corresponds to a change in the system frequency due to a temperature according to the interpolated temperature-time function; and
change the digital frequency variable in the least significant bit at the determined instant.

9. A method for compensating temperature-dependent changes in a magnetic field of a magnetic resonance device as claimed in claim 1, comprising:
capturing temperature data of the cold mass using the at least one temperature sensor;
calculating a frequency shift based on the captured temperature data; and
adjusting the frequency of the output signal based on the calculated frequency shift.

10. The method as claimed in claim 9, further comprising:
generating the output signal using the radio-frequency unit as a function of the calculated frequency shift.

11. The method as claimed in claim 9 for compensating temperature-dependent changes in the magnetic field of a magnetic resonance device including a cold mass with a main magnet, at least one temperature sensor configured to ascertain temperature data of the cold mass, a control unit configured to receive the temperature data from the at least one temperature sensor, and a radio-frequency unit configured to output an output signal to generate a radio-frequency field, wherein a system frequency of the magnetic resonance device depends on a temperature of the cold mass, and wherein the control unit and/or the radio-frequency unit are configured to adjust a frequency of the output signal based on the temperature data, wherein the control unit and/or the radio-frequency unit are configured to control a frequency of the output signal using a digital frequency variable and generate a synthesis signal with the system frequency as a function of the output signal, capture a change in temperature of the cold mass using the at least one temperature sensor, interpolate a temperature-time function as a function of the captured change in temperature of the cold mass, determine an instant at which a change in the digital frequency variables in a least significant bit causes a change in frequency of the synthesis signal, which corresponds to a change in the system frequency due to a temperature according to the interpolated temperature-time function, and change the digital frequency variable in the least significant bit at the determined instant, the method comprising:
capturing a change in temperature of the cold mass by means of the temperature sensor;
interpolating a temperature-time function of the temperature as a function of the captured change in temperature;
determining an instant at which a change in a digital frequency variables in a least significant bit causes a change in frequency of the synthesis signal, which corresponds to a change in the system frequency due to a temperature according to the interpolated temperature-time function;
adjusting the digital frequency variables in the least significant bit at the determined instant; and
generating the output signal by means of the radio-frequency system as a function of the calculated frequency shift, wherein an output frequency of the output signal is dependent on a value of the adjusted digital frequency variable, and a synthesis signal with a system frequency as a function of the output signal.

12. A non-transitory computer program product which is loadable directly into a processor of a programmable controller, with program code to execute steps of a method as claimed in claim 9 when the non-transitory program product is executed on the controller.
